(19) United States
(12) Patent Application Publication
(10) Pub. No.: US 2010/0157000 A1
(43) Pub. Date: Jun. 24, 2010

(54) LIQUID EJECTION HEAD, LIQUID EJECTING APPARATUS, AND ACTUATOR

(75) Inventor: Koji SUMI, Shiojiri-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/640,870

(22) Filed: Dec. 17, 2009

(30) Foreign Application Priority Data
Dec. 22, 2008 (JP) 2008-326472

(51) Int. Cl. B41J 2/045; H01L 41/04

(52) U.S. Cl. 347/70; 310/330

(57) ABSTRACT

A liquid ejection head includes: a pressure generating chamber communicating with a nozzle hole; a vibrating film placed on one side of the pressure generating chamber; and a pressure generating element including a piezoelectric layer formed between a first and a second electrodes placed on the vibrating film. The pressure generating element generates displacement when voltage is applied across the first and the second electrodes to make pressure in the pressure generating chamber change, while a neutral plane of stress made by the displacement is so configured as to exist in the first electrode, and a layer on the pressure generating chamber side relative to the first electrode includes a laminar film or an amorphous film.

### BACKGROUND

1. Technical Field

The present invention relates to liquid ejection heads, liquid ejecting apparatuses, and actuators. In particular, the invention is useful when it is applied to, for example, a liquid ejection head for ejecting liquid from a nozzle hole.

2. Related Art

An ink jet printing heads, using deflection deformation of a piezoelectric element, is put to practical use. Such an ink jet printing head includes a pressure generating chamber that communicates with a nozzle hole; and part of the pressure generating chamber includes a vibrating film. The vibrating film is deformed by the piezoelectric element to apply pressure to ink in the pressure generating chamber, which makes an ink drop be discharged from the nozzle hole. Here, the piezoelectric element includes a lower electrode as a first electrode, an upper electrode as a second electrode, and a piezoelectric layer formed between the first and second electrodes. The piezoelectric element generates displacement when voltage is applied across the first and second electrodes. In addition, there is proposed a vibrating film having a laminated structure of silicon oxide provided on the pressure generating chamber side and a ceramic vibrating plate such as zirconium oxide provided on the piezoelectric element side (for example, JP-A-2005-260003 or Japanese Patent No. 3,379,538 discloses the above configuration.)

However, zirconium oxide or the like of a vibrating film in the past forms a columnar crystal layer; if a point defect exists in the columnar crystal layer, a crack is made starting from the point defect. This may cause destruction of the columnar crystal layer.

The reason for the above is as follows. Deformation of a piezoelectric element brings distortion stress in the piezoelectric element and in the vibrating film. When the piezoelectric element and a vibrating plate are deformed towards the pressure generating chamber side, the distortion stress acts as compression stress in a region above a neutral plane, whereas the distortion stress acts as tensile stress under the neutral plane. That is, the compression stress and the tensile stress are substantially cancelled at the neutral plane. The neutral plane is so designed as to exist in a first electrode. Therefore, the tensile stress acts on the vibrating film. Thus, if the crystal structure of a region in which the tensile stress acts is columnar, stress in a plane direction (in a direction perpendicular to a film thickness direction) acts on a boundary surface of the crystal in such a manner that the stress splits the boundary surface. Therefore, if a point defect exists in the vicinity of the boundary surface, a crack starting from the point defect may extend, resulting in destruction of the crystal.

Such a difficulty is not limited to liquid ejection heads as are typically used in ink jet printing heads. Similar difficulties may also arise in actuators used in other devices.

### SUMMARY

An advantage of some aspects of the invention is to provide a liquid ejection head, a liquid ejection apparatus and an actuator, each of which includes a vibrating film and a piezoelectric element, and even if a point defect exists in the vibrating film and the piezoelectric element, no destruction will occur.

According to a first aspect of the invention, there is provided a liquid ejection head including: a pressure generating chamber communicating with a nozzle hole; a vibrating film provided on one side of the pressure generating chamber; and a pressure generating element including a piezoelectric layer formed between a first and a second electrodes placed on the vibrating film. The pressure generating element generates displacement when voltage is applied across the first and second electrodes, which causes pressure in the pressure generating chamber to change. A neutral plane of the stress caused by the displacement is so designed as to exist in the first electrode, and a layer on the pressure generating chamber side relative to the first electrode includes a laminar film or an amorphous film.

According to this aspect of the invention, because the neutral plane of the stress exists in the first electrode, the displacement of the piezoelectric element causes tensile stress to act on a layer under the neutral plane. If a point defect exists in a region in which the tensile stress acts, shearing force acts on this point defect in a plane direction. However, according to this aspect of the invention, the region includes a laminar film or an amorphous film. To be more specific, a grain boundary in parallel to a film thickness direction does not exist. Therefore, the point defect may be prevented from growing into a crack. This makes it possible to prevent such a point defect from causing a crack in a vibrating plate, resulting in bringing stable operation of the liquid ejection head over a long period of time.

It is preferable that a region in which the displacement causes compression stress include a columnar crystal film. In this case, a grain boundary in a film thickness direction does not exist in the region in which the compression stress acts. Therefore, a point defect in the region in which the compression stress acts may be prevented from growing into a crack, and also prevented from causing a crack in both of a compression region and a tensile region of a vibrating plate, partitioned by the neutral plane.

Moreover, it is preferable that a region in which the displacement causes the compression stress include a columnar crystal film and be configured with at least two layers of which boundary surface is heteroepitaxial. In this case, even if a plurality of layers whose compositions differ from one another are formed, no boundary surface is formed between the layers because these layers have the same crystal structure. To be more specific, the plurality of layers have a structure that is substantially equivalent to a structure of one-piece columnar crystal. This makes it possible to prevent compression stress from causing a point defect to develop into a crack.

In addition, according to a second aspect of the invention, there is provided a liquid ejecting apparatus including the liquid ejection head according to the first aspect of the invention. According to the second aspect of the invention, a vibrating plate of the liquid ejection head may be prevented from cracking, resulting in bringing stable operation of the liquid ejecting apparatus over a long period of time.

According to a third aspect of the invention, there is provided an actuator including: a pressure generating chamber communicating with a nozzle hole; a vibrating film provided on one side of the pressure generating chamber; and a pressure generating element including a piezoelectric layer formed between a first and a second electrodes placed on the vibrating film. The pressure generating element generates displacement when voltage is applied across the first and second electrodes, which causes pressure in the pressure generating chamber to change. A neutral plane of the stress caused by the displacement is so designed as to exist in the first electrode; and a layer on the pressure generating chamber side relative to the first electrode includes a laminar film or an amorphous film.

According to this aspect of the invention, because the neutral plane of the stress exists in the first electrode, the displacement of the piezoelectric element causes tensile stress to act on a layer under the neutral plane. If a point defect exists in a region in which the tensile stress acts, shearing force acts on this point defect in a plane direction. However, according to this aspect of the invention, the region includes a laminar film or an amorphous film. To be more specific, a grain boundary in parallel to a film thickness direction does not exist. Therefore, the point defect may be prevented from growing into a crack. This makes it possible to prevent such a point defect from causing a crack in a vibrating plate, resulting in bringing stable operation of the liquid ejection head over a long period of time.

It is preferable that a region in which the displacement causes compression stress include a columnar crystal film. In this case, a grain boundary in a film thickness direction does not exist in the region in which the compression stress acts. Therefore, a point defect in the region in which the compression stress acts may be prevented from growing into a crack, and also prevented from causing a crack in both of a compression region and a tensile region of a vibrating plate partitioned by the neutral plane.

Moreover, it is preferable that a region in which the displacement causes the compression stress include a columnar crystal film, and be configured with at least two layers of which boundary surface is heteroepitaxial. In this case, even if a plurality of layers whose compositions differ from one another are formed, no boundary surface is formed between the layers because these layers have the same crystal structure. To be more specific, the plurality of layers have a structure that is substantially equivalent to a structure of one-piece columnar crystal. This makes it possible to prevent compression stress from causing a point defect to develop into a crack.

### BRIEF DESCRIPTION OF THE DRAWINGS

The invention will be described with reference to the accompanying drawings, wherein like numbers reference like elements.

FIG. 1 is an exploded perspective view schematically illustrating a configuration of a printing head according to an embodiment of the invention.

FIG. 2A is a plan view illustrating the printing head according to an embodiment of the invention.

FIG. 2B is a cross sectional view illustrating the printing head according to an embodiment of the invention.

FIG. 3 is a cross sectional view illustrating a driving state of a piezoelectric element according to an embodiment of the invention.

FIG. 4 is a diagram illustrating a method for determining a neutral plane.

FIG. 5 is a diagram schematically illustrating a configuration of a printing apparatus according to an embodiment.

### DESCRIPTION OF EXEMPLARY EMBODIMENTS

The invention will be described in detail on the basis of embodiments as below.

### Embodiment

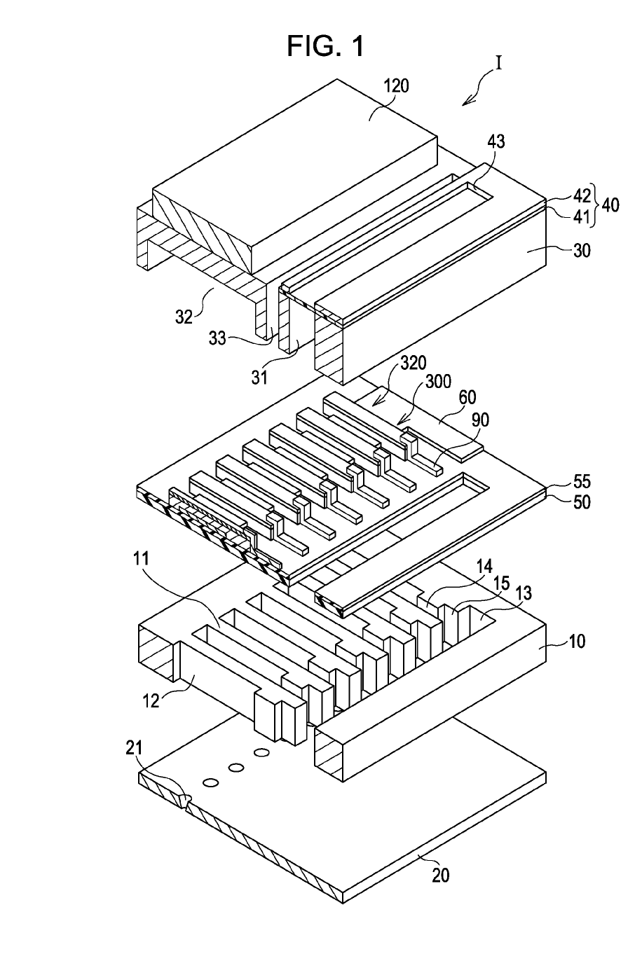

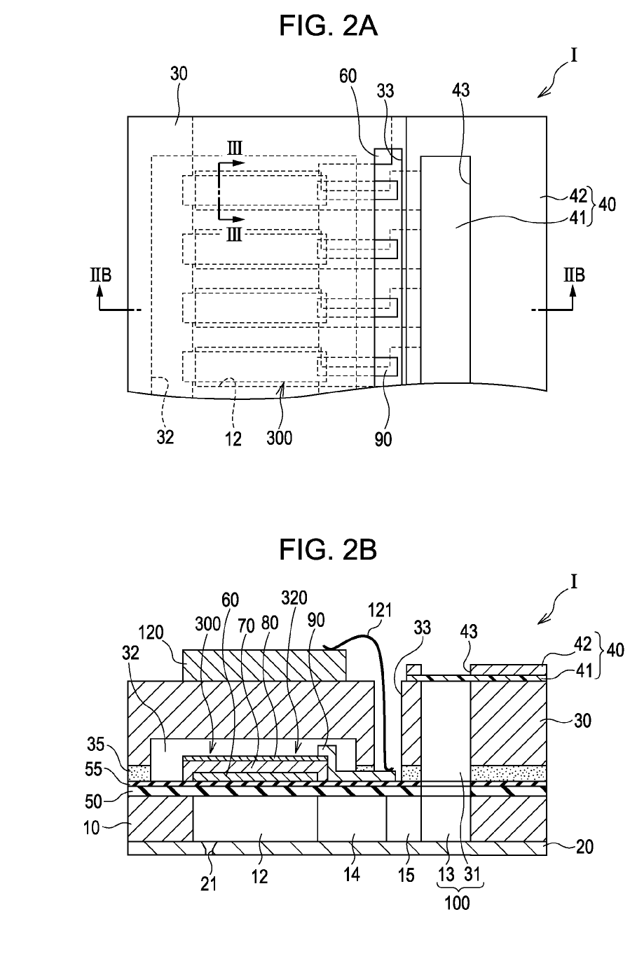

FIG. 1 is an exploded perspective view schematically illustrating a configuration of an ink jet printing head that is an example of a liquid ejection head according to an embodiment of the invention. FIG. 2A is a plan view of FIG. 1; and FIG. 2B is a cross sectional view taken along a line IIB-IIB in FIG. 2A.

A flow path forming board 10 according to this embodiment includes a silicon single crystal substrate. An elastic film 50 is formed on one surface side of the flow path forming board 10 as a silicon dioxide film whose main component is silicon oxide.

The flow path forming board 10 is provided with a plurality of pressure generating chambers 12 juxtaposing to one another in a width direction thereof. In addition, in a region outside the pressure generating chamber 12 of the flow path forming board 10 in the longitudinal direction, prepared is a communicating section 13. The communicating section 13 communicates with each of the pressure generating chambers 12 through an ink supply path 14 and a communicating path 15, both of which are provided with respect to each of the pressure generating chambers 12. The communicating section 13 communicates with a reservoir section 31 of a protective substrate described later, and constitutes part of a reservoir that is a common ink chamber among the pressure generating chambers 12. The width of ink supply path 14 is narrower than that of the pressure generating chamber 12. The ink supply path 14 maintains flow resistance of the ink flowing into the corresponding pressure generating chamber 12 from the communicating section 13 to be constant. Incidentally, according to this embodiment, the ink supply path 14 is formed by narrowing the width of the flow path from one side; the ink supply path 14 may also be formed by narrowing the width of the flow path from both sides. In addition, instead of narrowing the width of the flow path, the ink supply path 14 may also be formed by narrowing the flow path from a thickness direction.

In this embodiment, the flow path forming board 10 has a liquid flow path constituted of the pressure generating chamber 12, the communicating section 13, the ink supply path 14, and the communicating path 15.

In addition, on the opening surface side of the flow path forming board 10, a nozzle plate 20 in which nozzle holes 21 are bored is firmly fixed with an adhesive or a heat welding film. Each of the nozzle holes 21 communicates with a region in the vicinity of a tip and opposite to each ink supply path 14 of the pressure generating chambers 12. The nozzle plate 20 is made of, for example, glass ceramics, a silicon single crystal substrate, or stainless steel.

Meanwhile, on the side opposite to the opening surface side of the flow path forming board 10, the elastic film 50 is formed as described above. An insulator film 55 is formed on the elastic film 50 as a ceramic vibration plate whose main component is zirconium oxide. According to this embodiment, the elastic film 50 and the insulator film 55 constitute a vibrating film 56.

A first electrode 60, a piezoelectric layer 70, and a second electrode 80 are formed in layers on the insulator film 55 so that a piezoelectric element 300 which is a pressure generating element is formed; the piezoelectric element 300 is a portion including the first electrode 60, the piezoelectric layer 70, and the second electrode 80. In general, with one of the electrodes of the piezoelectric element 300 used as a common electrode, patterning of both the other electrode and the piezoelectric layer 70 is performed with respect to each of the pressure generating chambers 12. According to this embodiment, the first electrode 60 is used as a common electrode of the piezoelectric element 300, whereas the second electrode 80 is used as an individual electrode of the piezoelectric element 300. However, even if the first electrode 60 and the second electrode 80 are used in reverse for the conveniences of a driving circuit and wiring, no problem arises. Moreover, here, an actuator is constituted of the piezoelectric element 300, and the vibrating film in which driving of the piezoelectric element 300 makes displacement. In this connection, according to this embodiment, the elastic film 50, the insulator film 55, and the first electrode 60 function as a vibrating plate. However, as a matter of course, the invention is not limited to this configuration.

Here, as described above, the main component of the elastic film 50 is silicon oxide; and the elastic film 50 is disposed on one side of the flow path forming board 10 so as to define one side of the pressure generating chamber 12. However, because the elastic film 50 is made by thermal oxidation, the elastic film 50 forms an amorphous layer. The insulator film 55 placed on the elastic film 50 is a ceramic vibrating plate whose main component is zirconium oxide. In this embodiment, the insulator film 55 is formed by a CVD method. As a result, the insulator film 55 forms an amorphous layer. A ceramic vibration plate whose main component is zirconium oxide may also be formed by reactive sputtering. Also in this case, an amorphous film can be formed.

If lead zirconate titanate (PZT) is used as the piezoelectric layer 70, it is desirable that the first electrode 60 formed immediately above the insulator film 55 be a material whose conductivity does not largely change by scattering of lead oxide. Accordingly, platinum, iridium, or the like, is preferably used as a material of the first electrode 60. As an example, a titanium thin film is formed on the insulator film 55; and a platinum thin film and an iridium thin film are then formed on the titanium thin film one after another. After that, these films are calcinated together with the piezoelectric layer 70 and the second electrode 80 to form the first electrode 60. As a result, the first electrode 60 becomes a thin film having a thickness of for example 200 μm, which includes platinum as a main component, additionally including titanium oxide and iridium oxide. Here, according to this embodiment, an adjustment is made such that a neutral surface of stress, in distortion displacement of the piezoelectric layer 70, exists in the first electrode 60 (a specific adjustment method will be described in detail later). Here, a platinum layer of the first electrode 60 is a columnar crystal based on a crystal plane orientation (111).

The piezoelectric layer 70 is made of a piezoelectric material that has an electromechanical transducing action and is to be formed on the first electrode 60; in particular, among piezoelectric materials, metal oxide having a perovskite structure represented by a general formula ABO₃ is adopted. For example, materials suitable for the piezoelectric layer 70 include: a ferroelectric material such as lead zirconate titanate (PZT); and another ferroelectric material to which metal oxide such as niobium oxide, nickel oxide, and magnesium oxide are added. To be more specific, lead oxide (PbTiO₃), lead zirconate titanate (Pb (Zr, Ti) O₃), lead zirconate (PbZrO₃), lead titanate lanthanum ((Pb, La), TiO₃), lead lanthanum zirconate titanate ((Pb, La) (Zr, Ti) O₃), lead zirconate titanate magnesium niobium oxide (Pb (Zr, Ti) (Mg, Nb) O₃), or the like, can be used.

Here, the piezoelectric layer 70 has a columnar crystal structure. What is more, the piezoelectric layer 70 and the first electrode 60 constitute a heteroepitaxial structure in the boundary surface. Because of the heteroepitaxial structure, even if a thin film composition between the first electrode 60 and the piezoelectric layer 70 changes, the crystal structure does not change. Accordingly, the piezoelectric layer 70 and the first electrode 60 can be formed in such a structure that a boundary surface hardly occurs. To be more specific, the columnar crystal structure ranging from the first electrode 60 to the piezoelectric layer 70 can be effectively continued.

According to this embodiment, thickness of the piezoelectric layer 70 is about 1 through 5 μm, for example.

Incidentally, as a method for forming the piezoelectric layer 70, what is called a sol-gel process can be used. In the sol-gel process, for example, so-called sol made by dissolving and dispersing metal-organic matter in a solvent is applied and dried to become gel. Next, the gel is then calcinated at a high temperature to form the piezoelectric layer 70 made of metal oxide. Note that a method for forming the piezoelectric layer 70 is not particularly limited to the above one. For example, MOD (Metal-Organic Decomposition) method, PVD (Physical Vapor Deposition) method such as a sputtering method, or a laser ablation method may also be used.

A lead electrode 90 made of, for example, gold (Au) is connected to each second electrode 80, an electrode of the piezoelectric element 300. The lead electrode 90 is drawn from a position around an end portion of the ink supply path 14, and is extended on to the insulator film 55. Incidentally, the second electrode 80 can be suitably formed with an iridium thin film (an iridium oxide thin film after calcination).

A protective substrate 30, having the reservoir section 31 constituting at least a part of the reservoir 100, is joined with an adhesive 35 on the flow path forming board 10 on which the piezoelectric element 300 is formed, more specifically, on the first electrode 60, the insulator film 55 and the lead electrode 90. According to this embodiment, the reservoir section 31 penetrates the protective substrate 30 in a thickness direction thereof, and is formed extending in a width direction of the pressure generating chamber 12. As described above, the reservoir section 31 communicates with the communicating section 13 of the flow path forming board 10 so as to constitute a part of the reservoir 100, which is a common ink chamber for the each pressure generating chamber 12. In addition, only the reservoir section 31 may also be treated as a reservoir by partitioning the communicating section 13 of the flow path forming board 10 into a plurality of sections with respect to each pressure generating chamber 12. Moreover, for example, the flow path forming board 10 may be provided with only the pressure generating chambers 12 members (for example, the elastic film 50 and the insulator film 55) interposing between the flow path forming board 10 and the protective substrate 30 may be provided with the ink supply path 14 capable of communicating between a reservoir and each pressure generating chamber 12.

Further, a region facing the piezoelectric element 300 of the protective substrate 30 is provided with a piezoelectric element holding section 32 having such a space that movement of the piezoelectric element 300 is not interfered. The piezoelectric element holding section 32 is requested only to have such a space that the movement of the piezoelectric element 300 is not interfered; It does not matter whether the space may be sealed or not sealed.

In forming the protective substrate 30, it is preferable to use a material whose coefficient of thermal expansion is substantially the same as that of the flow path forming board 10, for example, a glass material or a ceramic material. According to this embodiment, a silicon single crystal substrate, which is the same material as that of the flow path forming board 10, is used to form the protective substrate 30.

Further, the protective substrate 30 has a through-hole 33 that penetrates the protective substrate 30 in a thickness direction thereof. A portion around an end of the lead electrode 90 drawn from the each piezoelectric element 300 is exposed in the through-hole 33.

A driving circuit 120 for driving the juxtaposed piezoelectric elements 300 is secured onto the protective substrate 30. For example, a circuit board or a semiconductor integrated circuit (IC), can be used as the driving circuit 120. The driving circuit 120 is electrically connected to the lead electrode 90 through connection wiring 121 formed with a conductive wire such as a bonding wire.

In addition, a compliance substrate 40 constituted of a sealing film 41 and a stationary plate 42 is joined to the protective substrate 30. The sealing film 41 is made of a flexible material whose rigidity is low, and seals one side of the reservoir section 31. The stationary plate 42 is made of a relatively rigid material. Because a region facing the reservoir 100 of this stationary plate 42 is complete removal in a thickness direction to be an opening 43, one side of the reservoir 100 is sealed only by the sealing film 41 having flexibility.

When an ink jet printing head according to this embodiment is operated, ink is taken in from an ink inlet connected to an external ink supply unit (not illustrated) so that the space ranging from the reservoir 100 to the nozzle hole 21 is filled with the ink. Next, according to a printing signal from the driving circuit 120, voltage is applied across the first electrode 60 and the second electrode 80, corresponding to each pressure generating chamber 12, so that the elastic film 50, the insulator film 55, the first electrode 60, and the piezoelectric layer 70 are subjected to deflection deformation. As a result, pressure in each pressure generating chamber 12 increases to make ink drops be discharged from the nozzle hole 21.

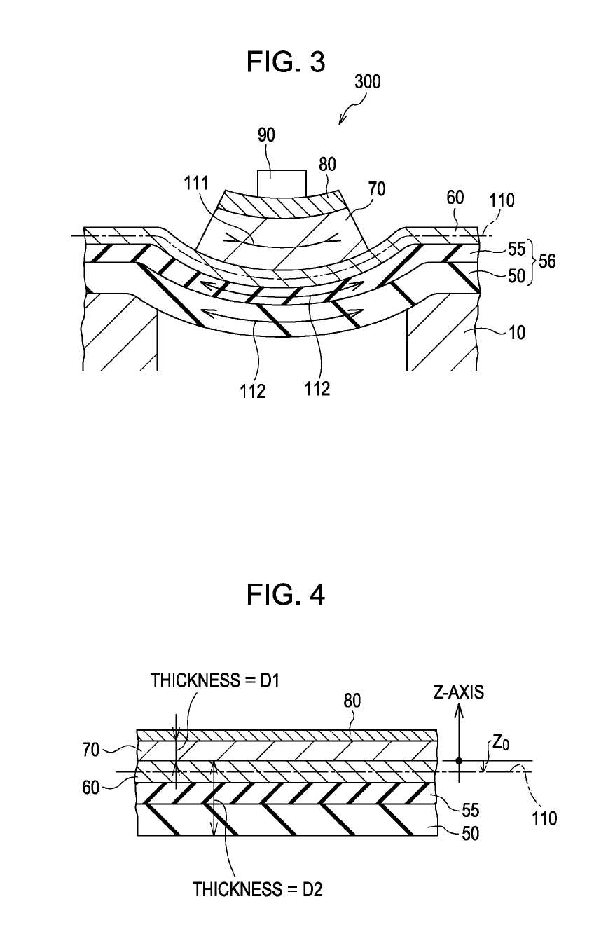

Here, as explicitly indicated in FIG. 3, a cross sectional view taken along a line III-III of FIG. 2A, which shows a driving state of the piezoelectric element 300, the neutral plane 110 for deflection stress in this embodiment is formed in the first electrode 60. Accordingly, when the piezoelectric element 300 is deformed into a convex shape toward the pressure generating chamber 12, tensile stress 112 occurs in the insulator film 55 and the elastic film 50, both of which are layers placed lower than the first electrode 60.

Here, because the insulator film 55 and the elastic film 50 are formed as amorphous layers, even if a point defect occurs in any of the amorphous layers, it is possible to prevent the point defect from growing into a crack. This is because the directions of the amorphous layers are in parallel with that of the tensile stress 112, that is, a grain boundary in parallel with a film thickness direction does not exist.

Meanwhile, the piezoelectric layer 70 and the second electrode 80 and part of the first electrode 60, all of which are formed in a region above the neutral plane 110, are formed to be columnar crystals. In the region, mentioned above, displacement of the piezoelectric element 300 generates compression stress. In addition, boundary surfaces among these layers are heteroepitaxial. In this case, although compression stress 111 acts in the region, any grain boundary in the film thickness direction substantially does not exist. Therefore, a point defect in the region in which the compression stress 111 acts may also be prevented from growing into a crack. Further, a point defect can be satisfactorily prevented from causing a crack in a vibrating plate or the like, in both of a compression and tensile regions which are partitioned by the neutral plane 110.

Here, how to determine the neutral plane 110 will be described below. As shown in FIG. 4, when a position at which the neutral plane 110 should exist is Z₀, the position Z₀ is calculated by the following equation (1), where a position of a boundary plane between the piezoelectric layer 70 and the first electrode 60 is defined as a reference plane.

$$\begin{matrix}Equation 1 & \\ {Z}_{0} = \frac{{\int }_{- D 2}^{0} \frac{Es}{1 - σ s} Z d Z + {\int }_{0}^{D 1} \frac{Ef}{1 - σ f} Z d Z}{\frac{EsAv}{1 - σ sAv} D 2 + \frac{E}{1 - σ f} D1} & ( 1 )\end{matrix}$$

where:

Es is a Young's modulus of each layer existing in a region under the reference plane (Z<0);
Ef is a Young's modulus of the piezoelectric layer 70;
σs is a Poisson ratio of each layer existing in a region under the reference plane (Z<0);
σf is a Poisson ratio of the piezoelectric layer 70;
EsAv is a mean of Young's moduli of the layers existing in a region under the reference plane (Z<0);
σsAv is a mean of Poisson ratios of the layers existing in a region under the reference plane (Z<0);
D1 is the thickness of the piezoelectric layer 70; and
D2 is the thickness of the layers under the piezoelectric layer 70

Therefore, if the above equation (1) is used to make an adjustment such that the position Z₀ exists in the first electrode 60.

### Other Embodiments

The embodiment of the invention has been described as above. However, a basic configuration of the invention is not limited to the configuration described above. For example, according to the above embodiment, the insulator film 55 to be combined with the elastic film 50 made of silicon oxide is made of zirconium oxide. In addition, the insulator film 55 may be made of silicon nitride (Si₃N₄), silicon carbide (SiC), titanium carbide (TiC), or the like in the combination with the elastic film. In these combinations, if the silicon oxide is formed by thermal oxidation, or if the silicon nitride, the silicon carbide, or the titanium carbide is formed by a CVD method, a desired amorphous film may be formed. In this case, the obtained film is not limited to an amorphous one. The same effects can be achieved so long as the film is a laminar one. Lanthanum nickel oxide (LNO) may be considered as a material of a laminar film.

Even if the silicon nitride (Si₃N₄), the silicon carbide (SiC), the titanium carbide (TiC), or the like, is used, it is necessary to adjust the neutral surface 110 to exist in the first electrode 60. However, using the above equation (1) to obtain the position Z₀ based on the relationship between the film thickness of each material and a Young's modulus, a desired adjustment can be easily made. The relationship between the film thickness of each material and a Young's modulus is shown in Table 1 as below.

TABLE 1

| | Film Thickness | Young's Modulus |
|---|---|---|
| | nm | GPa |
| SᵢO₂ | 1000 | 75 |
| Sᵢ₃N₄ | 300 | 200 |
| SᵢC | 400 | 150 |
| TᵢC | 400 | 150 |

In the above embodiment, the piezoelectric element 300 is disposed on the insulator film 55 as a pressure generating element. However, because the pressure generating element 300 has only to be formed above the insulator film 55, the pressure generating element 300 may be formed immediately above the insulator film 55, or may be layered above the insulator film 55 with another member interposed therebetween.

Moreover, according to the above embodiment, for example, a silicon single crystal substrate is taken as an example of the flow path forming board 10. However, the flow path forming board 10 is not particularly limited to this. For example, a silicon single crystal substrate whose crystal plane orientation is a plane (100) or a plane (110), may also be used. Further, a SOI substrate, a glass material, or the like, may also be used.

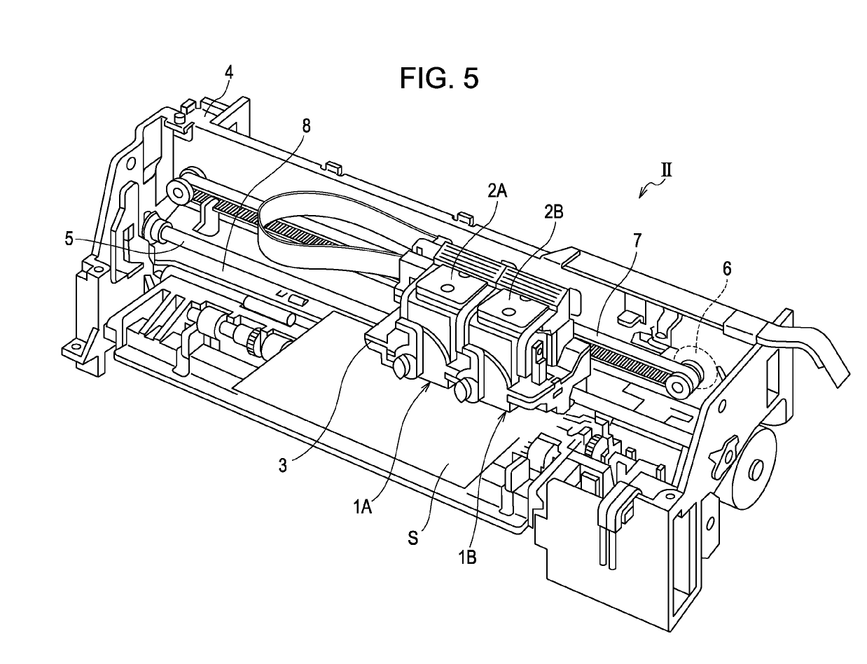

The ink jet printing head I constitutes a part of a printing head unit having an ink flow path that communicates with an ink cartridge and the like. The ink jet printing head I is built into an ink jet printing apparatus. FIG. 5 is a diagram schematically illustrating an example of such an ink jet printing apparatus.

In an ink jet printing apparatus II shown in FIG. 5, printing head units 1A and 1B each having the ink jet printing head I are provided with cartridges 2A and 2B respectively, each of which constitutes an ink supply unit. The cartridges 2A and 2B are mounted removably from the printing head units 1A and 1B, respectively. A carriage 3 equipped with the printing head units 1A and 1B, is attached to a carriage shaft 5 mounted to an apparatus main body 4. The carriage 3 can freely move in the carriage shaft direction. The printing head units 1A and 1B discharge, for example, a black ink composition and/or a color ink composition.

Driving force of a driving motor 6 is transferred to the carriage 3 through a plurality of gears (not shown) and a timing belt 7; then the carriage 3 equipped with the printing head units 1A and 1B moves along the carriage shaft 5. The apparatus main body 4 includes a platen 8 disposed along the carriage shaft 5. A print sheet S, a recording medium such as a piece of paper fed by a paper feeder (not shown) is wound on the platen 8 so as to be transported.

In the above description of the embodiments, an ink jet printing head is taken as an example of a liquid ejection head. However, the aspect of the invention covers wide range of liquid ejection heads. As a matter of course, the aspect of the invention can also be applied to liquid ejection heads ejecting a liquid other than ink. Other kinds of liquid ejection heads, for example, include printing heads used in image printing apparatuses such as a printer; color material ejection heads used to produce color filters of displays such as a liquid crystal display; electrode material ejection heads used to form electrodes of displays such as an organic electroluminescent display and an FED (field emission display); and living organic material ejection heads used for biochip manufacturing.

Moreover, the application of the invention is not limited to actuators that are installed in liquid ejection heads typified by ink jet printing heads. The aspect of the invention can also be applied to actuators mounted in other kinds of apparatuses.

What is claimed is:

1. A liquid ejection head comprising:
a pressure generating chamber communicating with a nozzle hole;
a vibrating film placed on one side of the pressure generating chamber; and
a pressure generating element including a piezoelectric layer formed between a first and a second electrodes placed on the vibrating film, the pressure generating element generates displacement when voltage is applied across the first and the second electrodes to make pressure in the pressure generating chamber change, wherein;
a neutral plane of stress made by the displacement is so configured as to exist in the first electrode, and
a layer on the pressure generating chamber side relative to the first electrode includes a laminar film or an amorphous film.

2. The liquid ejection head according to claim 1, wherein;
a region in which the displacement allows compression stress to act includes a columnar crystal film.

3. The liquid ejection head according to claim 1, wherein;
the region in which the displacement allows the compression stress to act includes a columnar crystal film and is configured with at least two layers of which boundary surface is heteroepitaxial.

4. A liquid ejecting apparatus comprising the liquid ejection head as in claim 1.

5. An actuator comprising:
a pressure generating chamber communicating with a nozzle hole;
a vibrating film provided on one side of the pressure generating chamber; and
a pressure generating element including a piezoelectric layer formed between a first and a second electrodes placed on the vibrating film, the pressure generating element generates displacement when voltage is applied across the first and the second electrodes to make pressure in the pressure generating chamber change, wherein;
a neutral plane of stress made by the displacement is so configured as to exist in the first electrode; and
a layer on the pressure generating chamber side relative to the first electrode is configured of a laminar film or an amorphous film.

6. The actuator according to claim 5, wherein
a region in which the displacement allows compression stress to act includes a columnar crystal film.

7. The actuator according to claim 5, wherein
the region in which the displacement allows the compression stress to act includes a columnar crystal film and is configured with at least two layers and the boundary surface of the two layers is heteroepitaxial.
